(19) United States
(12) Patent Application Publication
(10) Pub. No.: US 2026/0068662 A1
(43) Pub. Date: Mar. 5, 2026

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Hideaki KITAZAWA, Himeji Hyogo (JP)

(21) Appl. No.: 19/285,349

(22) Filed: Jul. 30, 2025

(30) Foreign Application Priority Data
Sep. 5, 2024 (JP) 2024-153440

(51) Int. Cl. H01L 23/367; H10D 80/00

(52) U.S. Cl. CPC H01L 23/3675; H10D 80/00

(57) ABSTRACT

The semiconductor device of the embodiment includes a first plate portion and a second plate portion. The semiconductor device includes a top electrode including a first surface, a second surface, and a plurality of first electrode pillars provided on the second surface side. The semiconductor device includes a bottom electrode including a third surface, a fourth surface, and a plurality of second electrode pillars provided on the third surface side. The semiconductor device includes a plurality of first semiconductor chips located between the first electrode pillars and the second electrode pillars, and electrically connected to the first electrode pillars and the second electrode pillars. The semiconductor device includes at least one first recess provided on the first surface and a width of the at least one first recess in a second direction perpendicular to the first direction being larger than a width of the first electrode pillars.

### CROSS-REFERENCE TO RELATED APPLICATION

This application is based upon and claims the benefit of priority from Japanese Patent Application No. 2024-153440, filed on Sep. 5, 2024, the entire contents of which are incorporated herein by reference.

### FIELD

Embodiments described herein relate generally to the semiconductor device.

### BACKGROUND

As a configuration in which a plurality of semiconductor elements are sandwiched between a top and a bottom electrode blocks, there is a pressure-contact semiconductor device. By applying the pressing force to the top and bottom electrode blocks from the outside, the internal electrical contacts are maintained.

Since such a semiconductor device operates under a high voltage and a large current, thermal expansion of the electrode due to an increase in the junction temperature may deteriorate reliability. Therefore, a semiconductor device with high reliability against heat is required.

### BRIEF DESCRIPTION OF THE DRAWINGS

FIG. 1 is a schematic cross-sectional view of the device 100 according to the first embodiment.

FIG. 2 is a schematic plan view of the device 100 according to the first embodiment.

FIG. 3 is a schematic cross-sectional view of the semiconductor device 200 according to the first modification of the first embodiment.

FIG. 4 is a schematic cross-sectional view of a semiconductor device 300 according to a second modification of the first embodiment.

FIG. 5 is a schematic cross-sectional view of a semiconductor device 400 according to a third modification of the first embodiment.

FIG. 6 is a schematic cross-sectional view of a semiconductor device 500 according to a fourth modification of the first embodiment.

FIG. 7 is a schematic cross-sectional view of the semiconductor device 600 according to the comparative example.

FIG. 8 is a schematic plan view of the semiconductor device 00 according to the comparative example.

FIG. 9 is a top view of a semiconductor chip.

### DETAILED DESCRIPTION

Hereinafter, embodiments of the present invention will be described with reference to the drawings. In this description, common reference numerals are given to common parts throughout the drawings. In addition, the dimensional ratios in the drawings are not limited to the illustrated ratios. Note that the present embodiment is not intended to limit the present invention.

In this specification, in order to illustrate the positional relationship of parts and the like, the upward direction of the drawings may be referred to as “upper”, and the downward direction of the drawings may be referred to as “lower”. Here, the terms “up” and “down” do not necessarily indicate a relationship with the direction of gravity.

### First Embodiment

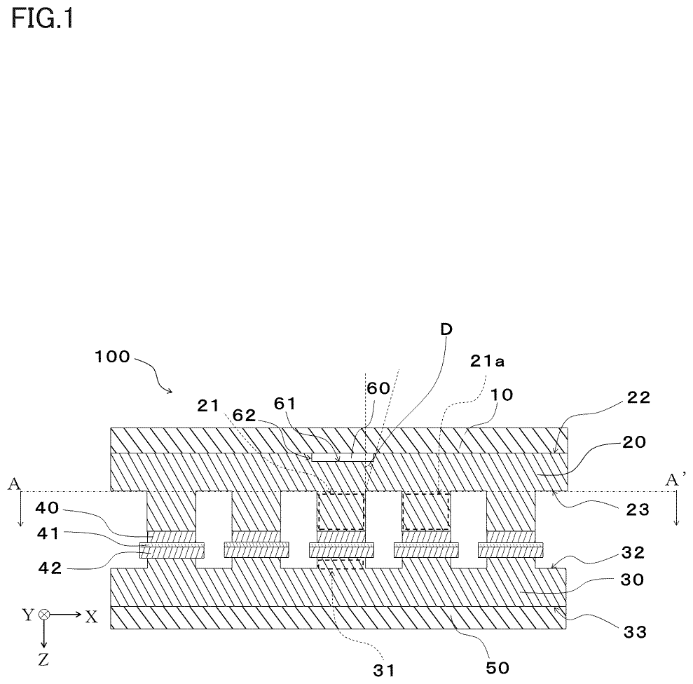

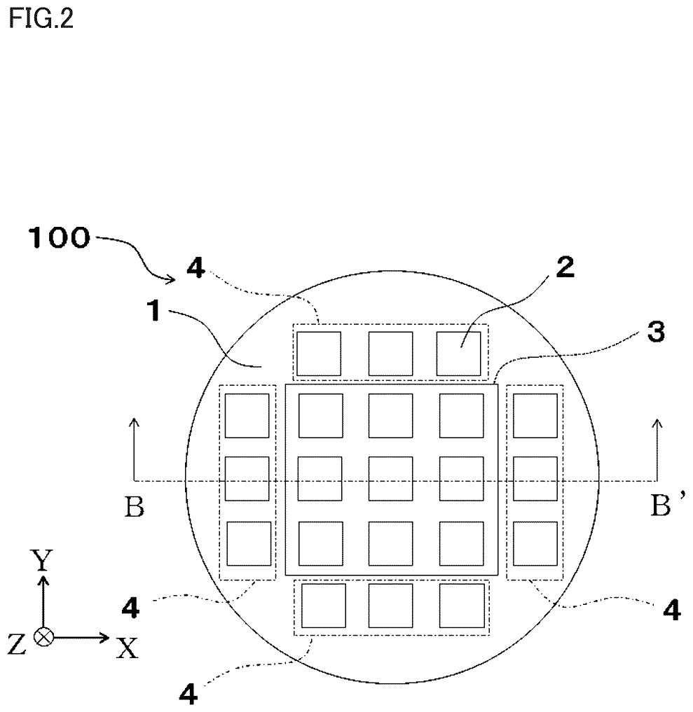

The semiconductor device 100 according to the first embodiment will be described referring to FIG. 1. FIG. 1 is the schematic cross-sectional view of the semiconductor device 100 according to the first embodiment, and FIG. 2 is the schematic plan view of the semiconductor device 100 according to the first embodiment.

According to FIG. 1, the semiconductor device 100 according to the first embodiment includes a first top electrode 20, a first bottom electrode 30, and a plurality of semiconductor chips 41. Since the plurality of semiconductor chips 41 are joined by the first top electrode 20 and the first bottom electrode 30 while being pressed from above and below, the semiconductor device 100 is called the pressure-contact semiconductor device or the like. The semiconductor chip 41 is located between the first top electrode 20 and the first bottom electrode 30. The first top electrode 20 and the first bottom electrode 30 are sandwiched between the first cooling plate 10 (the first plate portion) and the second cooling plate 50 (the second plate portion). Here, a direction from the first cooling plate 10 toward the second cooling plate 50 is referred to as the Z-direction (the first direction). A direction perpendicular to the Z-direction is defined as the X-direction (the second direction), and a direction perpendicular to the X-direction and the Z-direction is defined as the Y-direction. The first cooling plate 10 and the second cooling plate 50 are made of, for example, a metallic material such as Cu (copper) or Al (aluminum).

The first top electrode 20 has the first surface 22 that contacts the first cooling plate 10 in the Z-direction, and the second surface 23 that faces the first surface 22 in the Z-direction. The first electrode pillars 21 electrically connected to the top surface of the semiconductor chip 41 are provided on the second surface 23. In FIG. 1, the first electrode pillar 21 is indicated by a dotted line. The first bottom electrode 30 includes the fourth surface 33 provided in contact with the second cooling plate 50 and the third surface 32 that faces the fourth surface 33 in the direction opposite to the Z-direction. On the third surface 32, the second electrode pillars 31 are provided which are electrically connected to the bottom surface of the semiconductor chip 41. In FIG. 1, the second electrode pillar 31 is indicated by a dotted line.

The first top electrode 20 and the first electrode pillars 21 are integrally formed and are made of a metallic material such as Cu. In addition, the first bottom electrode 30 and the second electrode pillars 31 are integrally formed and are made of a metallic material such as Cu. The first thermal compensation plates 40 are provided between each of the first electrode pillars 21 and each of the semiconductor chip 41, and the second thermal compensation plates 42 are provided between each of the second electrode pillars 31 and each of the semiconductor chip 41. The second thermal compensation plates 42 are provided to relieve thermal stresses experienced by the semiconductor chip 41 when the semiconductor chip 41 is pressed against the first top electrode 20 and the first bottom electrode 30. The second thermal compensation plates 42 include a conductive material such as, for example, Mo (molybdenum).

The semiconductor chip 41 is, for example, an IGBT (Insulated Gate Bipolar Transistor). The semiconductor chip 41 is not limited to the IGBT, and may be a MOSFET (Metal Oxide Semiconductor Field Effect Transistor or a diode. Further, the semiconductor chip 41 may be a device using SiC (silicon carbide) other than Si (silicon).

FIG. 2 is the schematic plan view of the semiconductor device 100 and shows the X-Y plan view of the A-A′ cross-section of FIG. 1. In addition, the cross-sectional view of FIG. 1 shows the X-Z plan view in the B-B′ cross-section of FIG. 2.

According to FIG. 2, in the semiconductor device 100 according to the first embodiment, the plurality of electrode blocks 2 are arranged in the plane of the plate portion 1. The plate portion 1 shows a virtual plane located between the first top electrode 20 and the first bottom electrode 30. The electrode block 2 includes the first electrode pillar 21 (the first electrode pillars 21), the second electrode pillar 31 (the second electrode pillars 31), and the semiconductor chip 41 sandwiched by the first thermal compensation plate 40 and the second thermal compensation plate 42, between the pillars. The plate portion 1 may be disc-shaped.

Also, as shown in FIG. 1, the first top electrode 20 has at least one first recess 60 on the first surface 22. The first recess 60 is provided on the first surface 22, above where the semiconductor chip 41 is located. In other words, in the Z-direction, at least a part of the first recess 60 overlaps the semiconductor chip 41.

Further, the first recess 60 is provided above the semiconductor chip 41 provided inside the outermost periphery of the plurality of semiconductor chips 41 disposed in the plane of the plate portion 1. That is, in the semiconductor device 100 according to the first embodiment, one or more first recesses 60 are provided in a central region 3 indicated by a dotted line inside the peripheral region 4 indicated by a dashed-dotted line in FIG. 2. The reason will be described later. Note that the number of the semiconductor chips 41 provided in the central region 3 is not limited by the present embodiment. The first recess 60 may have the same rectangular shape as that of the semiconductor chip 41 or may have a circular shape. Here, the inner side refers to a part or an area close to the center of the plate portion 1.

Furthermore, the first recess 60 provided on the first surface 22 of the first top electrode 20 includes a bottom surface of the recess 61 and a side surface of the recess 62. The side surface of the recess 62 and the bottom surface of the recess 61 are contiguous. When viewed from Z-direction or −Z direction, the side surface of the recess 62 is provided so as to be located between the first electrode pillar 21 located directly below the first recess 60 and another adjacent first electrode pillar 21a in the X-direction. That is, the side surface of the recess 62 does not overlap with another first electrode pillar 21a in the Z-direction. Here, another first electrode pillar 21a and the first electrode pillar 21 are adjacent to each other in the X-direction. In FIG. 1, the another first electrode pillar 21a is indicated by dotted lines. Here, the first recess 60 may be formed by, for example, pressing using a mold or etching by corroding a metal.

Further, a resin-made support (not shown) and a PCB (Printed Circuit Board) including a gate wiring for applying a voltage to the gate electrode may be provided around the semiconductor chips 41, the first electrode pillar 21, and the second electrode pillar 31.

The semiconductor device 100 according to the first embodiment described in detail above is electrically conductive by being pressurized from above and below, and exhibits a function as a semiconductor device.

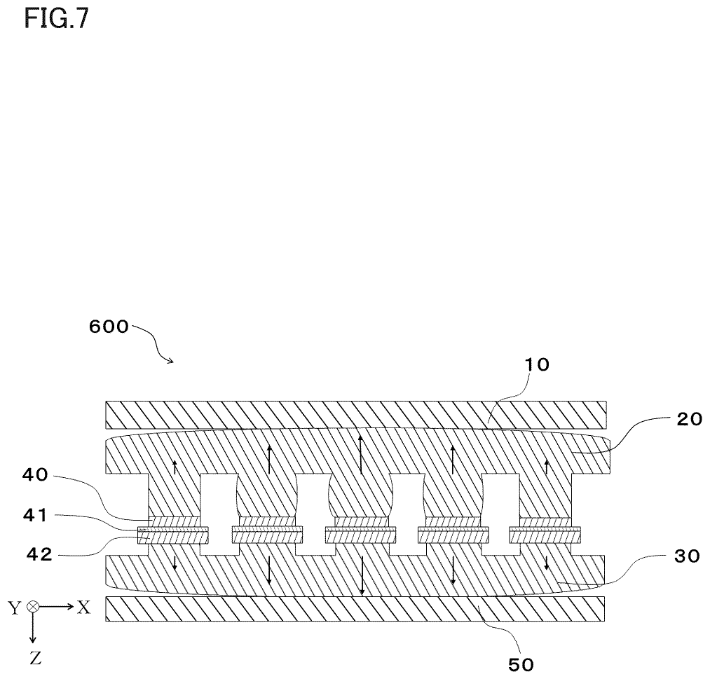

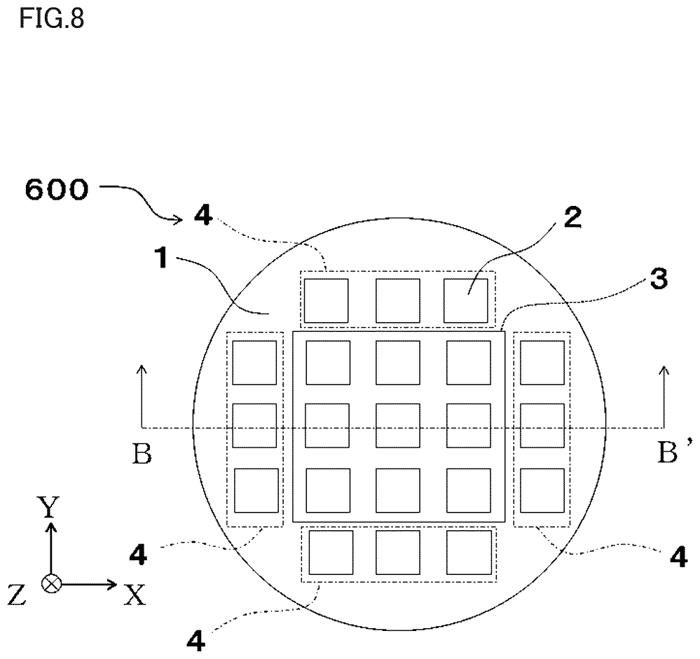

Here, a semiconductor device 600 which is a comparative example of the semiconductor device 100 according to the first embodiment will be described. FIG. 7 is the schematic cross-sectional view of the semiconductor device 600 according to the comparative example, and FIG. 8 is the schematic plan view of the semiconductor device 600 according to the comparative example. A cross-sectional view of the semiconductor device 600 illustrated in FIG. 7 corresponds to a cross-sectional view of the semiconductor device 100 illustrated in FIG. 1. A cross-sectional view of the semiconductor device 600 illustrated in FIG. 8 corresponds to a cross-sectional view of the semiconductor device 100 illustrated in FIG. 2. The semiconductor device 600 differs from the semiconductor device 100 in that it does not include the first recess 60. The semiconductor device 600 has a structure that is less reliable than the semiconductor device 100.

In each of the semiconductor device 100 according to the first embodiment and the semiconductor device 600 according to the comparative example, the junction temperature between the semiconductor chip 41 and the first top electrode 20 (or the first bottom electrode 30) increases to about 150° C. by energization or an environmental load test. In particular, the semiconductor chip 41 disposed in the central region 3 tends to have a higher temperature than the semiconductor chip 41 disposed in the peripheral region 4. This is because it is difficult to radiate heat and the wiring density tends to be high. Therefore, the first recess 60 provided on a part of the surface of the first top electrode 20 is preferably located around the central region 3 of the device (inside the peripheral region 4).

This property causes a loss of connectivity reliability in the peripheral region 4 and in the central region 3 due to different phenomena.

Here, a phenomenon of lowering in reliability of the semiconductor device 600 will be described in detail. In the semiconductor device 600, the first top electrode 20 and the first bottom electrode 30 thermally expand in the directions indicated by the arrows indicated by FIG. 7. Thermal expansion in the central region 3, which tends to be at high temperatures, becomes remarkable, while in the peripheral region 4, a reduction in the contacting pressure is caused. In the contact type semiconductor device, pressurization by a uniform plane is important for maintaining stable electrical resistance. Therefore, when the contact pressure in the peripheral region 4 decreases, the contact condition between the semiconductor chip 41 and the electrode becomes unstable, and the contact electric resistivity increases. In a portion where the contact electrical resistance is increased, local current concentration tends to occur, and melting marks due to point melting are generated. In addition, when alloying of Al and Si (silicon) proceeds, the resistivity decreases, so that the current is more concentrated, and the reliability is lowered due to the magnification of the melting mark. As described above, in the peripheral region 4 of the semiconductor device 600, the reliability decreases due to the contact-pressure decrease.

Furthermore, when the thermal expansion of the first top electrode 20 or the first bottom electrode 30 causes a thrust of the semiconductor chip 41 arranged in the central region 3, the semiconductor chip is mechanically stressed and an Al slide is generated. The Al slide is a phenomenon in which the Al wiring moves.

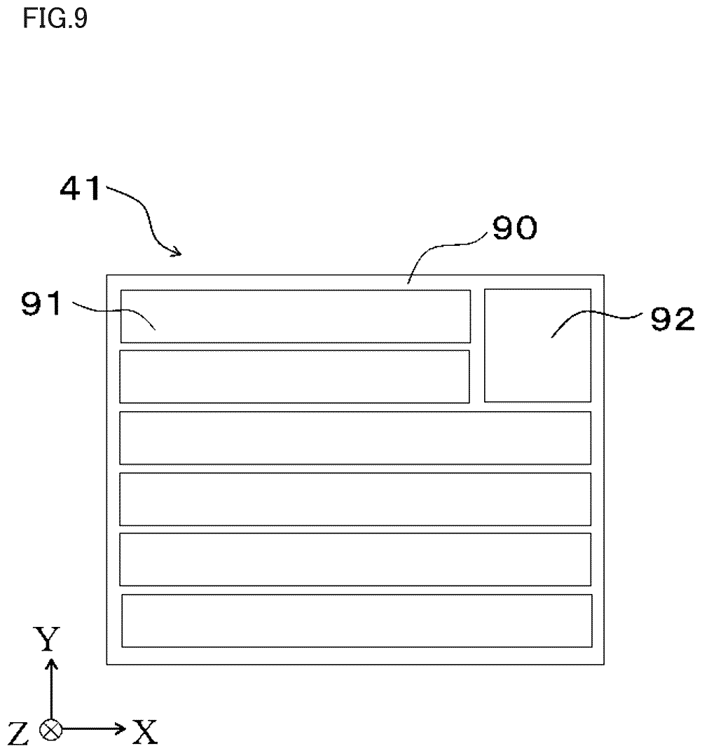

FIG. 9 shows a X-Y top view of the semiconductor chip 41. As shown in FIG. 9, the gate electrode 92 and the emitter electrode 91 are provided on the same X-Y plane, and a collector electrode (not shown) is provided on the back surface of the semiconductor chip 41. A gate wiring (not shown) that is electrically spaced apart from each other is disposed between a plurality of emitter electrodes 91, and is connected to the gate electrode 92. In addition, the surface protective film 90 is provided in a part of the semiconductor chip 41 where the electrodes are not provided. The surface protective film 90 is made of, for example, plastic. When the emitter electrode 91 slides due to the phenomenon of the Al slide described above, short-circuiting with the gate wiring (not shown) provided separately is caused.

In addition, when the mechanical stresses due to the thermal expansion of the first top electrode 20 or the first bottom electrode 30 are large, the Al slide itself may cause cracks in the surface protective film 90. If water or impurities present in the air around the semiconductor device 600 penetrate through the crack in the surface protective film 90, it may corrode the Al wiring and cause a disconnection failure.

As described above in detail, the reliability of the semiconductor device 600 may be decreased due to the concentration of electrolysis and the Al slide.

### Effect of the First Embodiment

An effect of the semiconductor device 100 according to the first embodiment will be described.

In the semiconductor device 100, the first recess 60 is provided on a part of the first top electrode 20. Therefore, when thermal expansion of the first top electrode 20 or the first bottom electrode 30 occurs, heat and pressure can be dissipated by the first recess 60. For example, as shown in FIG. 1, when the angle D formed by the junction between the side wall of the first electrode pillar 21 and the second surface 23 and the junction between the side surface of the recess 62 and the bottom surface of the recess 61 is 45° or less, heat and pressure can be well dissipated. In the semiconductor device 100, the angle D is less than or equal to 45°, and the side surface of the recess 62 does not overlap with another first electrode pillar 21a in the Z-direction. Here, another first electrode pillar 21a and the first electrode pillar 21 are adjacent to each other in the X-direction. Such a semiconductor device 100 has good heat dissipation properties and can be applied to the entire first electrode pillars. The magnitude of the first recess is not limited to the present embodiment, and may be provided so as not to affect the electrical properties when the pressure is applied.

In this way, the semiconductor device 100 can prevent point-melting due to uneven thermal expansion of the first top electrode 20 or the first bottom electrode 30, and can suppress short-circuiting due to the Al sliding. That is, the reliability of the semiconductor device 100 can be improved.

### (First Modification)

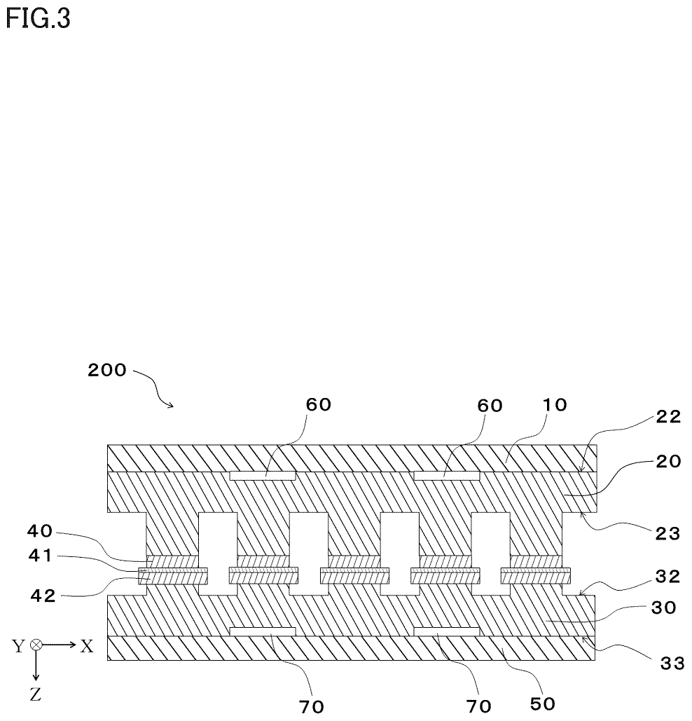

FIG. 3 is the schematic cross-sectional view of the semiconductor device 200 according to the first modification of the first embodiment.

In the semiconductor device 200, the first recess 60 is provided in the first top electrode 20, and the second recess 70 is provided in the first bottom electrode 30. The first recess 60 and the second recess 70 face each other in the Z-direction. Further, two or more of the first recesses 60 and the second recesses 70 may be provided.

Since the semiconductor chip 41 generates heat on the front and back surfaces, the thermal expansion of the electrodes can be more effectively reduced in the semiconductor device 200 in which the recesses are provided on both front and back surfaces of the semiconductor chip 41 than in the semiconductor device 100 in which the at least one first recess 60 is provided on one surface.

### (Second Modification)

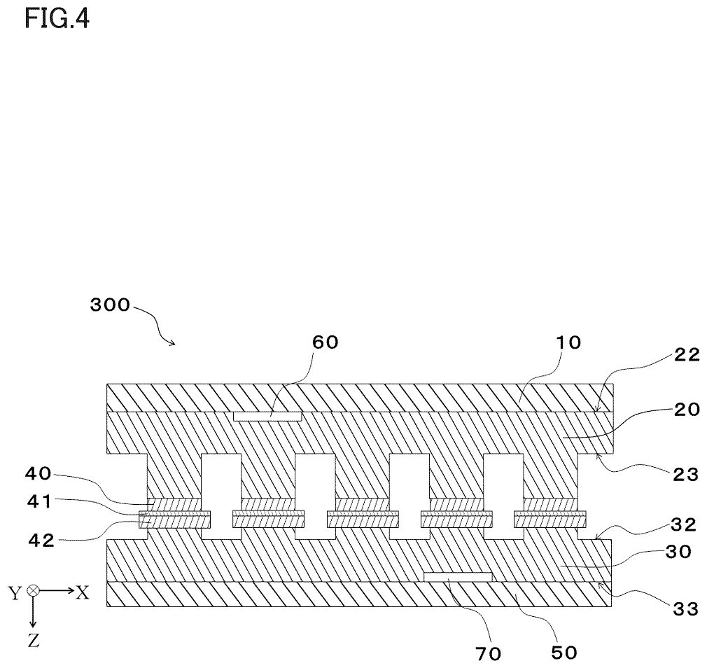

FIG. 4 is the schematic cross-sectional view of a semiconductor device 300 according to a second modification of the first embodiment.

In the semiconductor device 300, the first recess 60 provided in the first top electrode 20 and the second recess 70 provided in the first bottom electrode 30 are respectively provided at arbitrary positions. In the semiconductor device 300, the first recess 60 provided in the first top electrode 20 and the second recess 70 provided in the bottom electrode as in the semiconductor device 200 may not face each other in the Z-direction.

As the actual device, a case in which various types of chips, such as the diode or the MOSFET, are mixed, is assumed. In such a case, heat generation tends to occur on the semiconductor chip having a high current density. Therefore, by providing the recess above the semiconductor chip with high-current-density, heat is diffused, and the thermal expansion of the electrode can be effectively alleviated. In particular, in the semiconductor device in which the diode and the MOSFET are mixed, since heat generation in the diode is large, the recess may be provided above the diode.

### (Third Modification)

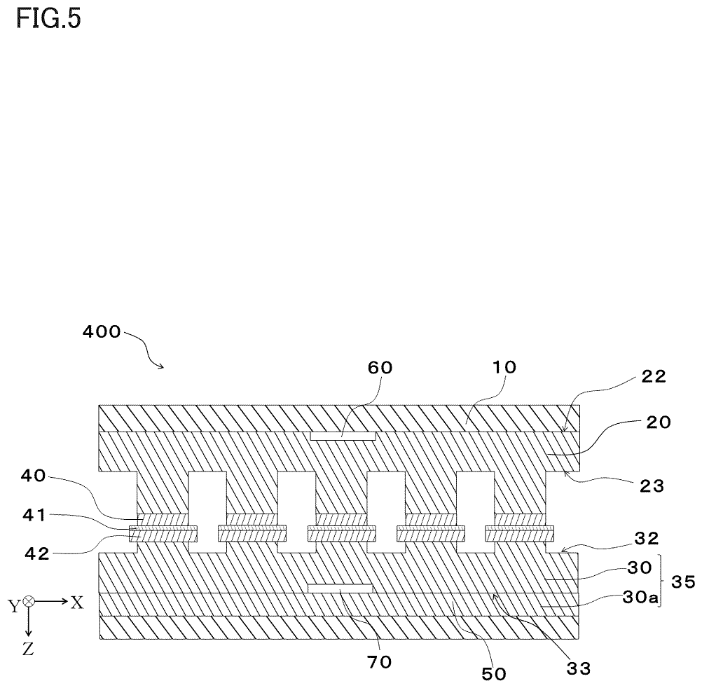

FIG. 5 is the schematic cross-sectional view of the semiconductor device 400 according to the third modification of the first embodiment.

In the semiconductor device 400, the second bottom electrode 30a is further provided below the first bottom electrode 30, on which a second recess 70 is provided. The second recess 70 is provided inside the bottom electrode 35, and the bottom electrode 35 includes the first bottom electrode 30 and the second bottom electrode 30a. Similarly, the effect of alleviating the thermal expansion is obtained. In addition, the second recess 70 can be provided while maintaining the contacting area with the second cooling plate 50 through the second bottom electrode 30a, and highly heat dissipation can be obtained. The second bottom electrode 30a is made of the same material as that of the first bottom electrode 30, for example, Cu or the like.

### (Fourth Modification)

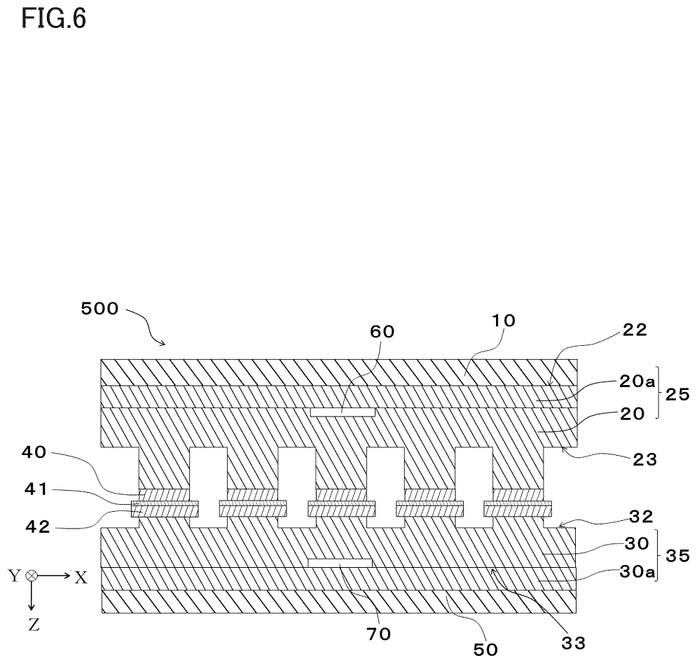

FIG. 6 is the schematic cross-sectional view of a semiconductor device 500 according to a fourth modification of the first embodiment.

In the semiconductor device 500, a second top electrode 20a is further provided on the first top electrode 20 on which the first recess 60 is provided. As a result, the first recess 60 is provided inside the top electrode 25. Further, the second bottom electrode 30a is further provided below the first bottom electrode 30 on which the second recess 70 is provided. As a result, the second recess 70 is provided inside the bottom electrode 35. Also in the present embodiment, the first recess 60 and the second recess 70 can alleviate the thermal expansion. In addition, since the contact area between the first cooling plate 10 and the top electrode 25 and the contact area between the second cooling plate 50 and the bottom electrode 35 can be maintained, the heat dissipation property is higher than that of the semiconductor device 100.

While certain embodiments have been described, these embodiments have been presented by way of example only, and are not intended to limit the scope of the inventions. These novel embodiments can be implemented in various other forms, and various omissions, replacements, and modifications can be made without departing from the gist of the invention. These embodiments and variations thereof fall within the scope and spirit of the invention, and fall within the scope of the invention described in the claims and equivalents thereof.

The above-described embodiments can be summarized in the following technical proposals.

(Technical proposal 1) A semiconductor device, including:
a first plate portion;
a second plate portion provided separately from the first plate portion;
a top electrode including
   a first surface provided in contact with the first plate portion,
   a second surface provided opposite to the first surface in a first direction from the first plate portion to the second plate portion, and
   a plurality of first electrode pillars provided on the second surface side;
a bottom electrode including
   a third surface,
   a fourth surface provided in contact with the second plate portion and the fourth surface being provided opposite to the third surface in the first direction, and
   a plurality of second electrode pillars provided on the third surface side;
a plurality of first semiconductor chips located between each of the first electrode pillars and each of the second electrode pillars, each of the first semiconductor chips being electrically connected to each of the first electrode pillars and each of the second electrode pillars; and
at least one first recess provided on the first surface and a width of the at least one first recess in a second direction perpendicular to the first direction being larger than a width of the first electrode pillars.

(Technical proposal 2) The semiconductor device according to technical proposal 1,
wherein the first semiconductor chips include the second semiconductor chips arranged in the second direction,
wherein the second semiconductor chips include a third semiconductor chip and a fourth semiconductor chip,
wherein the third semiconductor chip is located at the outermost periphery of the second semiconductor chips,
wherein the fourth semiconductor chip is located inside the third semiconductor chip, and
wherein the at least one first recess is located between the fourth semiconductor chip and the first plate portion.

(Technical proposal 3) The semiconductor device according to technical proposal 1,
wherein the at least one first recess includes a bottom surface of the recess and a side surface of the recess, and the side surface of the recess is contiguous with the bottom surface of the recess,
wherein the first electrode pillars include a third electrode pillar and a fourth electrode pillar, the third electrode pillar is provided directly below the at least one first recess, and the fourth electrode pillar is provided adjacent to the third electrode pillar in the second direction, and
wherein the side surface of the recess does not overlap the third electrode pillar and the fourth electrode pillar in the first direction.

(Technical proposal 4) The semiconductor device according to technical proposal 1,
wherein the fourth surface further includes a second recess.

(Technical proposal 5) The semiconductor device according to technical proposal 1,
wherein the fourth surface further includes a second recess, and
wherein the second recess and the at least one first recess face each other in the first direction.

(Technical proposal 6) The semiconductor device according to technical proposal 4,
wherein the first semiconductor chips include an IGBT and a diode, and
wherein at least one of the at least one first recess facing the diode in a opposite direction to the first direction and the second recess facing the diode in a opposite direction to the first direction is provided.

(Technical proposal 7) The semiconductor device according to technical proposal 4,
wherein at least one of the at least one first recess facing one of the first semiconductor chips having a high current density and the second recess facing one of the first semiconductor chips having a high current density is provided.

(Technical proposal 8) The semiconductor device according to technical proposal 4,
wherein at least one of the bottom electrode and the top electrode is further provided with an electrode.

(Technical proposal 9) The semiconductor device according to technical proposal 4, further including:
a plurality of first thermal compensation plates, each of the first thermal compensation plates being provided between each of the first electrode pillars and each of the first semiconductor chips; and
a plurality of second thermal compensation plates, each of the second thermal compensation plates being provided between each of the second electrode pillars and each of the first semiconductor chips.

What is claimed is:

1. A semiconductor device, comprising:
a first plate portion;
a second plate portion provided separately from the first plate portion;
a top electrode including
a first surface provided in contact with the first plate portion,
a second surface provided opposite to the first surface in a first direction from the first plate portion to the second plate portion, and
a plurality of first electrode pillars provided on the second surface side;
a bottom electrode including
a third surface,
a fourth surface provided in contact with the second plate portion and the fourth surface being provided opposite to the third surface in the first direction, and
a plurality of second electrode pillars provided on the third surface side;
a plurality of first semiconductor chips located between each of the first electrode pillars and each of the second electrode pillars, each of the first semiconductor chips being electrically connected to each of the first electrode pillars and each of the second electrode pillars; and
at least one first recess provided on the first surface and a width of the at least one first recess in a second direction perpendicular to the first direction being larger than a width of the first electrode pillars.

2. The semiconductor device according to claim 1,
wherein the first semiconductor chips include the second semiconductor chips arranged in the second direction,
wherein the second semiconductor chips include a third semiconductor chip and a fourth semiconductor chip,
wherein the third semiconductor chip is located at the outermost periphery of the second semiconductor chips,
wherein the fourth semiconductor chip is located inside the third semiconductor chip, and
wherein the at least one first recess is located between the fourth semiconductor chip and the first plate portion.

3. The semiconductor device according to claim 1,
wherein the at least one first recess includes a bottom surface of the recess and a side surface of the recess, and the side surface of the recess is contiguous with the bottom surface of the recess,
wherein the first electrode pillars include a third electrode pillar and a fourth electrode pillar, the third electrode pillar is provided directly below the at least one first recess, and the fourth electrode pillar is provided adjacent to the third electrode pillar in the second direction, and
wherein the side surface of the recess does not overlap the third electrode pillar and the fourth electrode pillar in the first direction.

4. The semiconductor device according to claim 1,
wherein the fourth surface further includes a second recess.

5. The semiconductor device according to claim 1,
wherein the fourth surface further includes a second recess, and
wherein the second recess and the at least one first recess face each other in the first direction.

6. The semiconductor device according to claim 4,
wherein the first semiconductor chips include an IGBT and a diode, and
wherein at least one of the at least one first recess facing the diode in a opposite direction to the first direction and the second recess facing the diode in a opposite direction to the first direction is provided.

7. The semiconductor device according to claim 4,
wherein at least one of the at least one first recess facing one of the first semiconductor chips having a high current density and the second recess facing one of the first semiconductor chips having a high current density is provided.

8. The semiconductor device according to claim 4,
wherein at least one of the bottom electrode and the top electrode is further provided with an electrode.

9. The semiconductor device according to claim 4, further comprising:
a plurality of first thermal compensation plates, each of the first thermal compensation plates being provided between each of the first electrode pillars and each of the first semiconductor chips; and
a plurality of second thermal compensation plates, each of the second thermal compensation plates being provided between each of the second electrode pillars and each of the first semiconductor chips.
